(19) United States
(12) Patent Application Publication
(10) Pub. No.: US 2025/0112194 A1
(43) Pub. Date: Apr. 3, 2025

(54) 3D CHIP PACKAGE STRUCTURE

(71) Applicant: WHALECHIP CO., LTD., Taipei City (TW)

(72) Inventors: Kun-Hsien LEE, Taipei City (TW); Chih-Hsien LEE, Taipei City (TW); Huey-Jen LIM, Taipei City (TW)

(21) Appl. No.: 18/792,494

(22) Filed: Aug. 1, 2024

(30) Foreign Application Priority Data
Sep. 28, 2023 (CN) 202311271715.6
Jan. 2, 2024 (CN) 2024100113802

(51) Int. Cl. H01L 23/00; G11C 5/14; H01L 25/18; H10B 80/00

(52) U.S. Cl. CPC H01L 24/29; H01L 24/32; H01L 25/18; G11C 5/147; H01L 24/16; H01L 24/73; H01L 2224/16225; H01L 2224/29034; H01L 2224/32145; H01L 2224/73253; H10B 80/00

(57) ABSTRACT

A 3D chip packaging structure with a memory device. The memory device includes a memory wafer layer and a connecting layer. The memory wafer layer includes at least one memory partition. The connecting layer is disposed on one side of the memory wafer layer. The connecting layer includes at least one connecting quiet zone and at least one connecting area. The at least one connecting quiet zone and the at least one connecting area are corresponding to the at least one memory partition. The at least one connecting quiet zone is adjacent to the at least one connecting area. The area of the at least one connecting quiet zone is equal to or larger than the at least one connecting area.

### CROSS-REFERENCES

This application claims the priority benefit of Chinese Patent Application Serial Number 202311271715.6, filed on Sep. 28, 2023, and Chinese Patent Application Serial Number 2024100113802, filed on Jan. 2, 2024, the full disclosure of which is incorporated herein by reference.

### TECHNICAL FIELD

This present disclosure relates to a semiconductor package structure, and more particularly to a 3D chip package structure.

### DESCRIPTION OF RELATED ART

As the demand for data quantity becomes higher and higher, general memory can no longer meet the requirements for the high transmission of large data quantity. Thus, a high-bandwidth memory with smaller size, lower power consumption and higher bandwidth is proposed.

In order to achieve the high bandwidth of high-bandwidth memory, high-bandwidth memory must have more channels to perform data exchange. Currently, high-bandwidth memory can support channels up to 4 GB. Accordingly, the number of controllers used to control each channel has also increased.

Generally, the controllers are tightly packed in the logic circuit area for corresponding to the location of the channel connection point in the high-bandwidth memory. The controllers are electrically connected to the channel connection points through conductors. Therefore, the area between the high-bandwidth memory and the logic circuit area will be filled with the conductors. However, because of this configuration, it is difficult to design the chip circuit in the logic circuit area. For example, in order to maintain the configuration between the controllers and the high-bandwidth memory, the chip circuit in the logic circuit area needs to be redesigned to provide areas for the conductors and controllers. The internal circuit design of Silicon Intellectual Property (IP) chips is inherent. Since it is difficult to change the internal design of the IP chips, it will be difficult to directly apply it to the chip circuit design in the logic circuit area. It causes inconvenience in the design of integrated circuit chips.

### SUMMARY OF THE INVENTION

The embodiment of the present disclosure provides a 3D chip package structure for existing silicon intellectual property components, which can effectively simplify circuit design difficulty and reduce the overall design cost of integrated circuit (IC) chips. The purpose of improving the convenience of integrated circuit chip design is achieved.

One embodiment of the present disclosure provides a 3D chip package structure including a memory device. The memory device includes a memory wafer layer and a connecting layer. The memory wafer layer includes at least one memory partition. The connecting layer is disposed on one side of the memory wafer layer. Wherein the connecting layer corresponds to the at least one memory partition, the connecting layer includes at least one connecting quiet zone and at least one connecting area, the at least one connecting quiet zone is adjacent to the at least one connecting area, and the area of the at least one connecting quiet zone is equal to or larger than the at least one connecting area.

In the embodiments of the present disclosure, the connecting pad of the 3D chip package structure is disposed in the predefined connecting area, and the connecting quiet zone of the 3D chip package structure is not configured with the conductive pillar. The circuit component can be disposed in the 3D chip package structure according to the connecting quiet zone without changing its internal design. Therefore, the difficulty of circuit design is reduced, and the overall design cost of integrated circuit chips can be reduced with existing circuit components. The purpose of improving the convenience of integrated circuit chip design is achieved.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a 3D chip package structure in an embodiment of the present disclosure.

FIG. 2 is a schematic diagram of a 3D chip package structure in another embodiment of the present disclosure.

FIG. 3 is a schematic diagram of a configuration of the connecting quiet zone and the connecting area in an embodiment of the present disclosure.

FIG. 4 is another schematic diagram of the configuration of the connecting quiet zone and the connecting area in an embodiment of the present disclosure.

FIG. 5 is a schematic diagram of a structural of a memory device in an embodiment of the present disclosure.

FIG. 6 is another schematic diagram of the structural of the memory device in an embodiment of the present disclosure.

FIG. 7 is a schematic diagram of an electronic device in an embodiment of the present disclosure.

FIG. 8 is another schematic diagram of an electronic device in an embodiment of the present disclosure.

FIG. 9 is another schematic diagram of a 3D chip package structure in an embodiment of the present disclosure.

FIG. 10 is another schematic diagram of a 3D chip package structure in an embodiment of the present disclosure.

### DESCRIPTION OF THE INVENTION

The present invention will now be described more fully hereinafter with reference to the accompanying drawings, in which exemplary embodiments of the invention are shown. This present invention may, however, be embodied in many different forms and should not be construed as limited to the embodiments set forth herein. Rather, these embodiments are provided so that this present invention will be thorough and complete, and will fully convey the scope of the present invention to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the invention. This description is made for the purpose of illustration of the general principles of the invention and should not be taken in a limiting sense. The scope of the invention is best determined by reference to the appended claims.

Moreover, the terms “include”, “contain”, and any variation thereof are intended to cover a non-exclusive inclusion. Therefore, a process, method, object, or device that comprises a series of elements not only include these elements, but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

In the following embodiment, the same reference numerals are used to refer to the same or similar elements throughout the invention.

Please refer to FIG. 1. FIG. 1 is a schematic diagram of a 3D chip package structure in an embodiment of the present disclosure. The 3D chip package structure 1 includes a memory device 10, a logic circuit device 30 and a substrate 50. The memory device 10 is connected to one side of the logic circuit device 30 through at least one conductive pillar 20. The substrate 50 is connected to the other side of the logic circuit device 30 through a plurality of connecting pads 40. The logic circuit device 30 is disposed between the memory device 10 and the substrate 50.

The memory device 10 includes a memory wafer layer 11 and a connecting layer 12. The connecting layer 12 is disposed at one side of the memory wafer layer 11. The memory wafer layer 11 includes at least one memory partition 111. In this embodiment, the memory wafer layer 11 includes a plurality of memory partitions 111 (111a, 111b), and the present disclosure is not limited thereto. The connecting layer 12 includes at least one connecting pad 121. The at least one connecting pad 121 is electrically connected to the corresponding memory partition 111. The at least one connecting pad 121 is in contact with the corresponding conductive pillar 20. In this embodiment, the present disclosure includes a plurality of connecting pads 121, and the present disclosure is not limited thereto.

More specifically, the connecting layer 12 includes at least one connecting quiet zone 13 and at least one connecting area 14. The at least one connecting quiet zone 13 is adjacent to the at least one connecting area 14. In this embodiment, the connecting layer 12 includes a plurality of connecting quiet zones 13 and a plurality of connecting areas 14. Each of the memory partitions 111 is corresponding to at least one connecting quiet zone 13 and corresponding to at least one connecting area 14. For example, one memory partitions 111a is corresponding to two connecting areas 14 (14a) and one connecting quiet zone 13 (13a), and the present disclosure is not limited thereto. In this embodiment, the at least one connecting pad 121 is only disposed in the at least one connecting area 14. In other words, the at least one connecting pad 121 is not disposed in any connecting quiet zone 13.

In one embodiment, the at least one connecting pad 121 is HBL or HBC.

In this embodiment, the memory device 10 is a High Bandwidth Memory (HBM).

In one embodiment, the connecting area 14 is adjacent to an edge of the memory partition 111. As shown in FIG. 1, the connecting areas 14 (14a) corresponding to the memory partition 111a are respectively disposed on the memory wafer layer 11, and the connecting areas 14 are adjacent to the left and right edges of the memory partition 111a.

The number of the at least one connecting quiet zone 13 and the at least one connecting area 14 are not limited to the figures of the present disclosure. For example, in FIG. 1, one memory partition 111a is corresponding to two connecting areas 14 and one connecting quiet zone 13. In other embodiments, one memory partition 111a may only correspond to one connecting area 14 and one connecting quiet zone 13. In other embodiments, the memory partition 111a may correspond to more than two connecting areas 14 and more than one connecting quiet zones 13.

The at least one conductive pillar 20 is only disposed in the at least one connecting area 14. In other words, any conductive pillar 20 is not disposed in any connecting quiet zone 13. As shown in FIG. 1, each of conductive pillar 20 disposed in the connecting areas 14 is connected to the corresponding connecting pad 121. In this embodiment, the number of the at least one conductive pillar 20 corresponds to the number of the at least one connecting pad 121. The number of the at least one conductive pillar 20 is same as the number of the at least one connecting pad 121. In one embodiment, the at least one conductive pillar 20 includes multiple metal layers, and the disclosure is not limited thereto.

The logic circuit device 30 is disposed on one side of the memory device 10. The logic circuit device 30 is connected to the memory device 10 through the plurality of conductive pillars 20. The logic circuit device 30 includes at least one circuit component 32. In one embodiment, the logic circuit device 30 further includes at least one memory controller 31. The at least one memory controller 31 is electrically connected to the corresponding conductive pillar 20. The at least one memory controller 31 is disposed in the logic circuit device 30 and corresponding to at least one connecting quiet zone 13 and/or at least one connecting area 14 of the connecting layer 12. For example, the logic circuit device 30 includes a plurality of memory controllers 31, part of the plurality of memory controllers 31 are connected to the conductive pillar 20 and therefore corresponding to the connecting area 14. In the embodiments, the plurality of memory controllers 31 are adjacent to one edge of the logic circuit device 30. For example, the memory controller 31 connected to the corresponded conductive pillar 20 is disponed in the edge of the logic circuit device 30. In other embodiments, the memory controllers 31 are corresponding to the connecting quiet zone 13, and the memory controllers 31 are disposed in the logic circuit device 30 and away from the edge of the logic circuit device 30. When the memory controllers 31 are corresponding to the connecting area 14, each of the memory controllers 31 may be in contact with the corresponding conductive pillar 20. When the memory controllers 31 are corresponding to the connecting quiet zone 13, each of the memory controllers 31 may be electrically connected to each of the conductive pillars 20 through a metal wiring layer (not shown) of the logic circuit device 30.

More specifically, the at least one circuit component 32 (32a. 32b) is deposed in the logic circuit device 30 and corresponding to the at least one connecting quiet zone 13. A vertical projection of the at least one circuit component 32 overlaps with a vertical projection of the at least one connecting quiet zone 13. The vertical projection of the at least one circuit component 32 does not overlap with a vertical projection of the at least one connecting area 14. For example, a circuit component 32a is corresponding to the connecting quiet zone 13 (13a) of the memory partition 111a, and the vertical projection of the circuit component 32a overlaps with the vertical projection of the connecting quiet zone 13 of the memory partition 111a. In this embodiment, the at least one circuit component 32 is a silicon intellectual property component.

In the embodiment of the 3D chip package structure 1 of the present disclosure, the 3D chip package structure 1 includes the connecting quiet zone 13 and the connecting area 14, the connecting pad 121 and the conductive pillar 20 are corresponding to the connecting area 14, and the connecting pad 121 and the conductive pillar 20 are centrally located in the connecting area 14. The circuit component 32 does not need to change and/or divide its circuit design to match the layout of the conductive pillars 20, and the circuit component 32 can be directly disposed in the logic circuit device 30 and corresponding to the connecting quiet zone 13. The circuit component 32 can directly apply the original circuit design structure to the integrated circuit design in the 3D chip package structure 1. The present disclosure can effectively simplify the difficulty of circuit design, and the overall design cost of integrated circuit chips is reduced by the existing circuit component 32. The purpose of improving the convenience of integrated circuit chip design is achieved.

In this embodiment, the 3D chip packaged structure 1 is a system on a chip (SoC) implemented by wafer stacking technology (3D Wafer on Wafer, WoW).

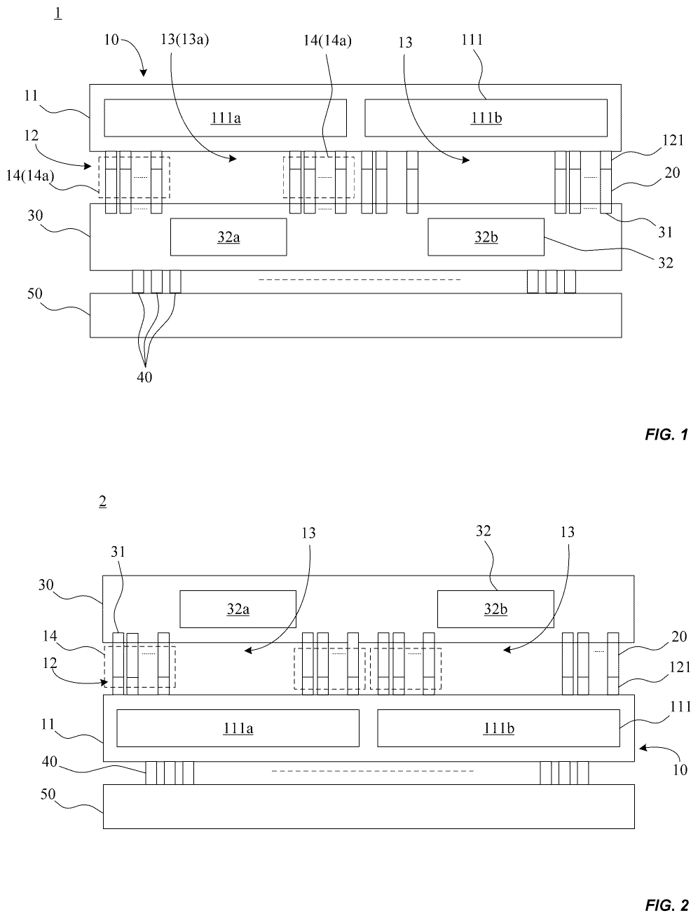

Please refer to FIG. 2, FIG. 2 is a schematic diagram of a 3D chip package structure in another embodiment of the present disclosure. The 3D chip package structure 2 includes the memory device 10, the logic circuit device 30 and the substrate 50 mentioned above. Wherein, the difference between FIG. 1 and FIG. 2 is that the memory device 10 is disposed between the logic circuit device 30 and the substrate 50, and the memory device 10 connected to the substrate 50 through the plurality of connecting pads 40. Therefore, the memory device 10 could be disposed one the top of the logic circuit device 30 or between the logic circuit device 30 and the substrate 50.

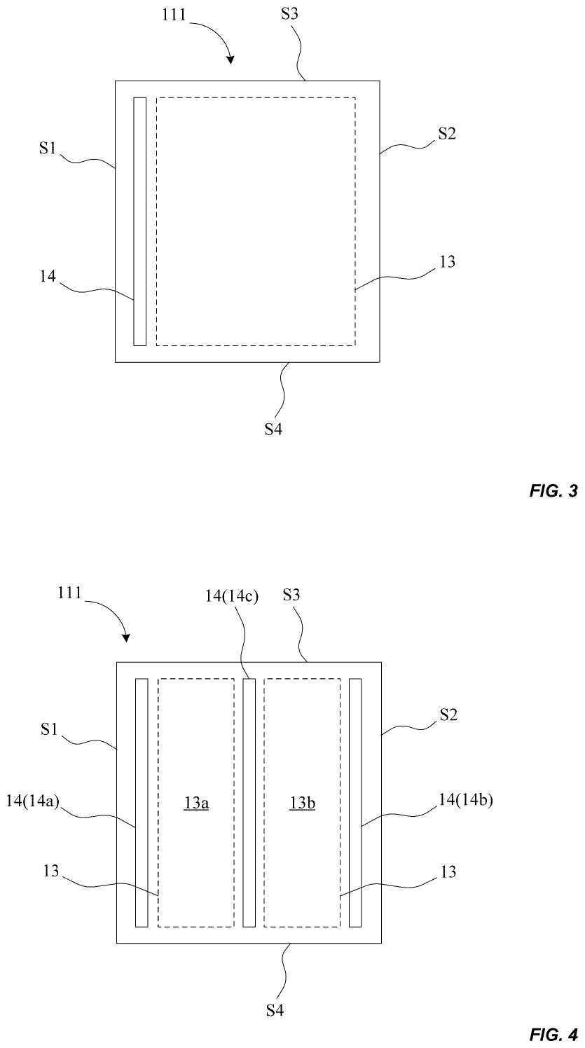

Please refer to FIG. 3. FIG. 3 is a schematic diagram of a configuration of the connecting quiet zone and the connecting area in an embodiment of the present disclosure. In this embodiment, one memory partition 111 is corresponding to one connecting quiet zone 13 and one connecting area 14. The connecting area 14 is adjacent to an edge S1 of the memory partition 111. The connecting quiet zone 13 is adjacent to an edge S2 of the memory partition 111. In this embodiment, the area of the connecting quiet zone 13 is larger than the area of the connecting area 14. In other embodiments, the area of the connecting quiet zone 13 is equal to the area of the connecting area 14. The area of the connecting quiet zone 13 is not smaller than the area of the connecting area 14.

In one embodiment, the connecting area 14 may be adjacent to the edge S3 of the memory partition 111, and the connecting quiet zone 13 may be adjacent to another edge S4 of the memory partition 111. The connecting area 14 can be adjacent to any edge (S1˜S4) of the memory partition 111.

Please refer to FIG. 4. FIG. 4 is a schematic diagram of the configuration of the connecting quiet zone and the connecting area in an embodiment of the present disclosure. In this embodiment, one memory partition 111 is corresponding to a plurality of connecting quiet zones 13 and a plurality of connecting areas 14. One connecting quiet zone 13 is located between two connecting areas 14, and the present disclosure is not limited thereto. In this embodiment, the connecting areas 14 may be away from the edges of the memory partition 111, and the present disclosure is not limited thereto. For example, the connecting areas 14c is located in the middle of the connecting layer 12 of the memory partition 111 and away from the edges (S1 and S2) of the memory partition 111.

In one embodiment, the area of each of the connecting quiet zones 13 is the same or different from each other. For example, the area of the connecting quiet zone 13a and the area of the connecting quiet zone 13b may be the same or different.

In one embodiment, the area of each of the connecting areas 14 is the same or different from each other. For example, the area of the connecting area 14a and the area of the connecting area 14b may be the same or different.

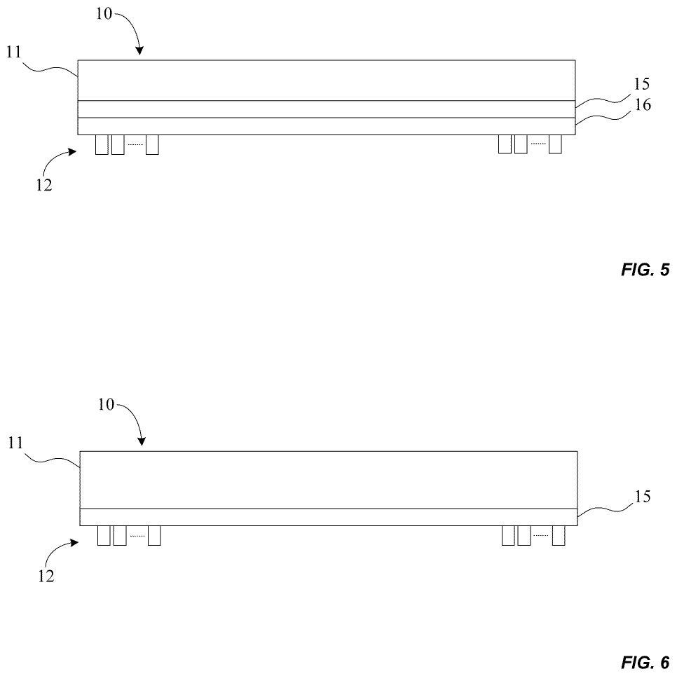

Please refer to FIG. 5. FIG. 5 is a schematic diagram of a structural of a memory device in an embodiment of the present disclosure. In this embodiment, the memory device 10 further includes a metal connecting layer 15 and at least one redistribution layer 16. The metal connecting layer 15 is disposed on one side of the memory wafer layer 11, and the at least one redistribution layer 16 is disposed on one side of the connecting layer 12. The at least one redistribution layer 16 is between the metal connecting layer 15 and the connecting layer 12. The at least one redistribution layer 16 is used to adjust the connection between at least one connection point of the metal connection layer 15 and the at least one connection pad 121 of the connection layer 12 for disposing the at least one connecting pad 121 in the corresponding connecting area 14 or the connecting quiet zone 13. The at least one connecting pad 121 of existing memory device 10 can be disposed in the corresponding connecting area 14 or connecting quiet zone 13 through the at least one redistribution layer 16. Therefore, the existing memory device 10 does not need to change the internal wiring design. The purpose of improving the convenience of integrated circuit chip design is achieved.

In one embodiment, the memory device 10 may include a plurality of redistribution layers 16 for connecting the at least one connection point of the connecting layer 15 to the connecting pads 121 of the connecting layer 12, and the present disclosure is not limited thereto.

In one embodiment, a thickness of the at least one redistribution layer 16 is 0.7 to 0.9 micrometer (μm), and the present disclosure is not limited thereto.

Please refer to FIG. 6. FIG. 6 is a schematic diagram of the structural of the memory device in an embodiment of the present disclosure. The difference between the embodiment of FIG. 6 and the embodiment of FIG. 5 is that the memory device 10 of FIG. 6 does not include the at least one redistribution layer 16. In the embodiment, the metal connecting layer 15 of the memory device 10 can be configured to correspond to the connecting area 14 or the connecting quiet zone 13 in the design stage of the memory device 10. The connecting pads 121 of the memory device 10 can be directly electrically connected to the metal connecting layer 15, and the connecting pads 121 are correspondingly disposed in the connecting area 14 or the connecting quiet zone 13. The memory device 10 does not need to establish the connection between the metal connecting layer 15 and the connecting pads 121 through additional process procedures (or layer). The purpose of improving the convenience of integrated circuit chip design is achieved.

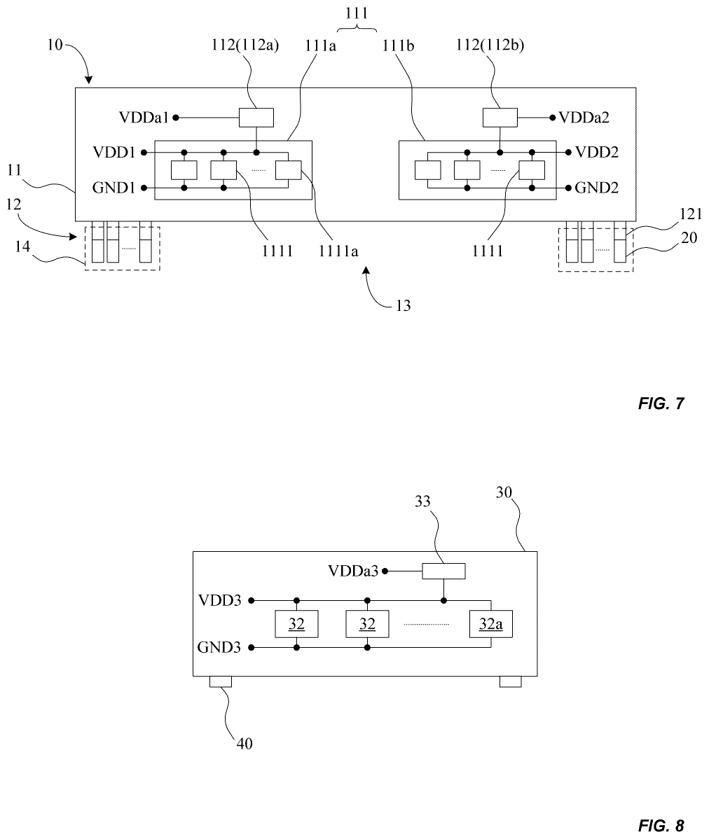

Please refer to FIG. 7. FIG. 7 is a schematic diagram of an electronic device in an embodiment of the present disclosure. In this embodiment, the electronic device is a memory device, and a circuit component of the electronic device is a storage unit. In this embodiment, the electronic device 10 includes a memory wafer layer 11. The memory wafer layer 11 includes at least one memory partition 111 and at least one compensation circuit 112. The at least one memory partition 111 is electrically connected to the at least one compensation circuit 112. In this embodiment, the memory wafer layer 11 includes a plurality of memory partitions 111 (ex. 111a, 111b), and the present disclosure is not limited thereto. In this embodiment, a plurality of conductive pillars 20 are electrically connected to an external circuit to individually receive a source voltage, a compensation source voltage, or a ground connection from the external circuit.

More specifically, the memory partition 111a includes a plurality of storage units 1111, and the storage units 1111 are connected in parallel to each other. One end of each of the storage unit 1111 is electrically connected to a corresponding power terminal VDD1 to receive the source voltage. The other end of each of the storage units 1111 is electrically connected to a corresponding ground terminal GND1 to be grounded. The power terminal VDD1 is electrically connected to the corresponding connecting pad 121 (As shown in FIG. 7, one connecting pad 121 is in the connecting area 14 located on the left side) for receiving the source voltage from the external circuit. The ground terminal GND1 is electrically connected to another corresponding connecting pad 121 (As shown in FIG. 7, another connecting pad 121 is in the connecting area 14 located on the left side) to be grounded through the corresponding connecting pad 121. The architecture of memory partition 111b is the same as memory partition 111a. The power terminal VDD2 is electrically connected to the corresponding connecting pad 121 (As shown in FIG. 7, the connecting pad 121 is in the connecting area 14 located on the right side) for receiving the source voltage from the external circuit. The ground terminal GND2 is electrically connected to the corresponding connecting pad 121 (As shown in FIG. 7, another connecting pad 121 is in the connecting area 14 located on the right side) for grounding through the corresponding connecting pad 121.

One end of the compensation circuit 112a is electrically connected to a compensation power terminal VDDa1. The other end of the compensation circuit 112a is electrically connected to one end of the storage units 1111 in the memory partition 111a. The compensation circuit 112a outputs a compensation voltage to one end of the electrically connected storage units 1111. The compensation power terminal VDDa1 is electrically connected to the corresponding connecting pad 121 (As shown in FIG. 7, another connecting pad 121 is in the connecting area 14 located on the left side) for receiving the compensation source voltage from the external circuit. One end of the compensation circuit 112b is electrically connected to a compensation power terminal VDDa2, and the other end of the compensation circuit 112b is electrically connected to one end of the storage units 1111 in the memory partition 111b. The compensation circuit 112b outputs a compensation voltage to one end of the electrically connected storage units 1111. The compensation power terminal VDDa2 is electrically connected to the corresponding connecting pad 121 (As shown in FIG. 7, another connecting pad 121 is in the connecting area 14 located on the right side) for receiving the compensation source voltage from the external circuit.

In this embodiment, the source voltage is only provided to the power terminal VDD1 through the corresponding connecting pad 121, and the location of the power terminal VDD1 is limited by the location of the connecting pad 121. When the input port (or input pin) of the source voltage is limited, the storage units 1111 need to receive the source voltage through the same power terminal VDD1. However, the source voltage is attenuated due to the trace length or process defects during the transmission process, so the storage unit 1111 (storage unit 1111a) that is far away from the power terminal VDD1 is unable to perform read and write operations with sufficient source voltage. Compared with other storage unit 1111, the storage unit 1111 that is far away from the power terminal VDD1 is more likely to cause errors in reading data due to the attenuated source voltage. Therefore, the present disclosure compensates for the attenuated source voltage by configuring the compensation circuit 112 in the electronic device and allowing the compensation circuit 112 to provide the compensation voltage to the storage unit 1111. The storage units 1111 electrically connected to the same power terminal VDD1 can have sufficient source voltage to perform corresponding read and write operations. The misjudgments in reading data are avoided.

Please refer to FIG. 2. In another embodiment, the power terminal VDD1, the ground terminal GND1, the compensation power terminal VDDa1, the power terminal VDD2, the ground terminal GND2 and the compensation power terminal VDDa2 are individually electrically connected to the corresponding connecting pads 40 that are connected to the memory wafer layer 11 and for receive the source voltage, the compensation source voltage, or the ground connection from the external circuit.

In this embodiment, the voltage value of the compensation source voltage is greater than the voltage value of the compensation voltage, and the voltage value of the source voltage is the same as the voltage value of the compensation voltage.

In this embodiment, the memory partition 111a is electrically connected to one compensation circuit 112. The number of compensation circuits 112 can be increased according to the number of storage units 1111 in the memory partition 111a and/or the source voltage requirements, and the present disclosure is not limited thereto.

In one embodiment, the compensation circuit 112 is a Low-dropout regulator (LDO).

Please refer to FIG. 8. FIG. 8 is another schematic diagram of an electronic device in an embodiment of the present disclosure. In this embodiment, the electronic device is a logic circuit device.

In this embodiment, the logic circuit device 30 includes a plurality of circuit components 32 and a compensation circuit 33. One end of each of the circuit components 32 is electrically connected to the power terminal VDD3. The other end of each of the circuit components 32 is electrically connected to a ground terminal GND3. Each of the circuit components 32 is connected in parallel to each other. The power terminal VDD3 is electrically connected to the corresponding connecting pad 40 for receiving a source voltage from the external circuit. The ground terminal GND3 is electrically connected to the corresponding connecting pad 40 so as to be grounded through the corresponding connecting pad 40.

One end of the compensation circuit 33 is electrically connected to a compensation power terminal VDDa3. The other end of the compensation circuit 33 is electrically connected to one end of each of the circuit components 32. The compensation circuit 33 outputs a compensation voltage to the electrically connected circuit component 32. The compensation power terminal VDDa3 is electrically connected to the corresponding connecting pad 40 for receiving the compensation source voltage from the external circuit.

Please refer to FIG. 2. In another embodiment, the power terminal VDD3, the ground terminal GND3 and the compensation power terminal VDDa3 are individually electrically connected to the corresponding connecting pads 121 that are connected to the memory wafer layer 11 and for receive the source voltage, the compensation source voltage, or the ground connection from the external circuit.

In this embodiment, the voltage value of the compensation source voltage is greater than the voltage value of the compensation voltage, and the voltage value of the source voltage is the same as the voltage value of the compensation voltage.

In this embodiment, the number of compensation circuits 33 is one. The number of compensation circuits 33 can be increased according to the number of circuit component 32 and/or source voltage requirements, and the present disclosure is not limited thereto.

In one embodiment, the compensation circuit 33 is a Low-dropout regulator (LDO).

In one embodiment, the circuit component 32 may be a controller circuit or a processor circuit, and the present disclosure is not limited thereto.

In this embodiment, the logic circuit device 30 is an integrated circuit device packaged by a wire bonding process.

When the number of the input port (or pin) of the source voltage is limited and the source voltage is attenuated due to trace length or process defects during the transmission process, the circuit components 32 (such as the circuit component 32a) far away from the power terminal VDD3 cannot operate with sufficient source voltage. The circuit components that are far away from the power terminal VDD3 are more likely to fail to operate properly due to unstable source voltage than other circuit components 32. Therefore, the present disclosure provides a compensation circuit 33 in an electronic device for providing a compensation voltage to the circuit components 32 to compensate the attenuated source voltage. Each of the circuit components 32 can operate with sufficient source voltage. The circuit components 32 can operate normally.

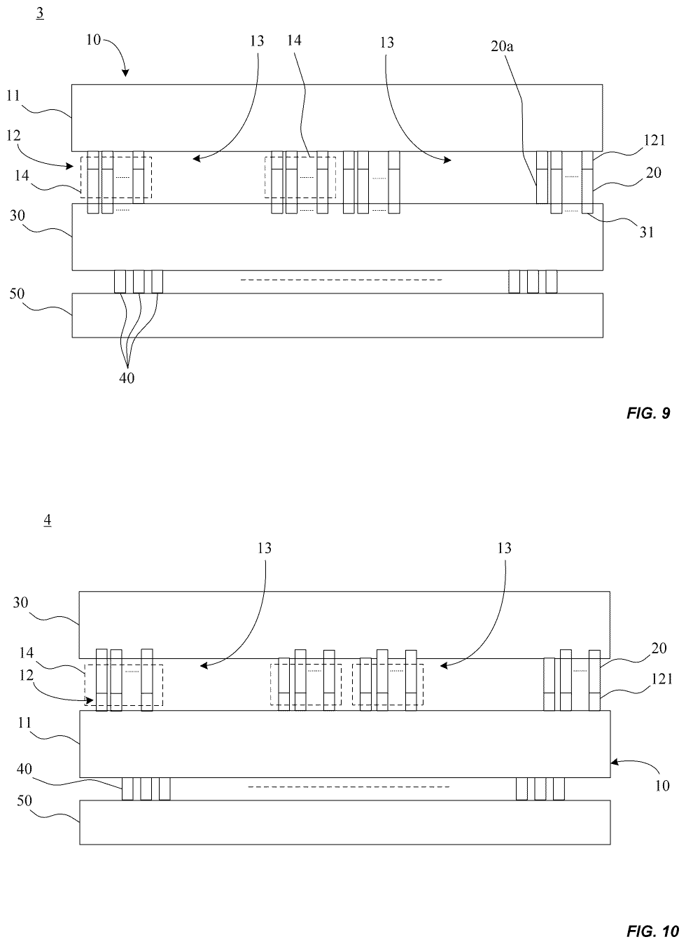

Please refer to FIGS. 1, 7, 8 and 9. FIG. 9 is another schematic diagram of a 3D chip package structure in an embodiment of the present disclosure. In this embodiment of the 3D chip package structure 3, the memory device 10 can be implemented by the embodiment of FIG. 7, and the logic circuit device 30 can be implemented by the embodiment of FIG. 8, and the present disclosure is not limited thereto.

In the embodiment, the memory device 10 can receive the source voltage, the compensation source voltage provided by the logic circuit device 30 through the conductive pillars 20 (20a), or be grounded through the logic circuit device 30.

The logic circuit device 30 is disposed on one side of the memory device 10 and is connected to the memory device 10 through the conductive pillars 20. In this embodiment, the logic circuit device 30 may include at least one memory controller 31. The at least one memory controller 31 is electrically connected to the corresponding conductive pillar 20. The at least one memory controller 31 is corresponding to at least one connecting quiet zone 13 and/or at least one connecting area 14 of the connecting layer 12.

The at least one circuit component 32 of the logic circuit device 30 is corresponding to the at least one connecting quiet zone 13. For example, circuit component 32a corresponds to the connecting quiet zone 13 of the memory partition 111a, and the vertical projection of the circuit component 32a overlaps with the vertical projection of the connecting quiet zone 13 of the memory partition 111a. In this embodiment, the at least one circuit component 32 is a silicon intellectual property (IP) component.

In this embodiment, the logic circuit device 30 is connected to the other side of the substrate 50 through the connecting pads 40. The logic circuit device 30 receives the source voltage and/or the compensation source voltage from the substrate 50, or the logic circuit device 30 is grounded through the substrate 50.

In this embodiment, the 3D chip packaging structure 3 is a system on a chip (SoC) implemented by wafer stacking technology (3D Wafer on Wafer, WoW).

Please refer to FIGS. 2, 7, 8 and 10. FIG. 10 is another schematic diagram of a 3D chip package structure in an embodiment of the present disclosure. In this embodiment of the 3D chip package structure 4, the memory device 10 can be implemented by the embodiment of FIG. 7, and the logic circuit device 30 can be implemented by the embodiment of FIG. 8, and the present disclosure is not limited thereto.

In the embodiment, the memory device 10 can receive the source voltage, the compensation source voltage through the conductive pillars 40, or be grounded through the substrate 50.

The logic circuit device 30 is disposed on one side of the memory device 10 and is connected to the memory device 10 through the conductive pillars 20. In this embodiment, the logic circuit device 30 may include at least one memory controller 31. The at least one memory controller 31 is electrically connected to the corresponding conductive pillar 20. The at least one memory controller 31 is corresponding to at least one connecting quiet zone 13 and/or at least one connecting area 14 of the connecting layer 12.

The at least one circuit component 32 of the logic circuit device 30 is corresponding to the at least one connecting quiet zone 13. For example, circuit component 32a corresponds to the connecting quiet zone 13 of the memory partition 111a, and the vertical projection of the circuit component 32a overlaps with the vertical projection of the connecting quiet zone 13 of the memory partition 111a. In this embodiment, the at least one circuit component 32 is a silicon intellectual property (IP) component.

In this embodiment, the logic circuit device 30 receives the source voltage and/or the compensation source voltage from the memory device 10, or the logic circuit device 30 is grounded through the memory device 10.

In this embodiment, the 3D chip packaging structure 4 is a system on a chip (SoC) implemented by wafer stacking technology (3D Wafer on Wafer, WoW).

According to above description, the connecting pads and conductive pillars between the memory device and the logic circuit device of the 3D chip packaged structure of the present disclosure are disposed in a predefined connecting area, and a connecting quiet zone without connecting pads and conductive pillars are formed in the 3D chip packaged structure. The circuit component can be disposed correspond to the connecting quiet zone, and the circuit component can be directly applied to the 3D chip packaged structure without changing its internal design. The difficulty of circuit design is simplified. The overall design cost of integrated circuit chips can be reduced by existing circuit components. The purpose of improving the convenience of integrated circuit chip design is achieved. Moreover, the electronic device of the present disclosure includes a compensation circuit. The compensation circuit is used to output the compensation voltage to the circuit component of the electronic device. The compensation voltage is used to supplement the source voltage of the circuit component that is far away from the power terminal. Therefore, circuit components connected to the same power terminal can operate with sufficient source voltage. The purpose of enabling the integrated circuit chip to stably provide source voltage to the circuit components is achieved.

It is to be understood that the term “comprises”, “comprising”, or any other variants thereof, is intended to encompass a non-exclusive inclusion, such that a process, method, article, or device of a series of elements not only include those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present invention has been explained in relation to its preferred embodiment, it does not intend to limit the present invention. It will be apparent to those skilled in the art having regard to this present invention that other modifications of the exemplary embodiments beyond those embodiments specifically described here may be made without departing from the spirit of the invention. Accordingly, such modifications are considered within the scope of the invention as limited solely by the appended claims.

1. A 3D chip package structure, comprising:
a memory device comprising:
a memory wafer layer comprising at least one memory partition; and
a connecting layer disposed at one side of the memory wafer layer;
wherein the connecting layer comprises at least one connecting quiet zone and at least one connecting area, the at least one connecting quiet zone and the at least one connecting area are corresponding to the at least one memory partition, the at least one connecting quiet zone is adjacent to the at least one connecting area, an area of the at least one connecting quiet zone is equal to or larger than the at least one connecting area.

2. The 3D chip package structure according to claim 1, wherein the connecting layer comprises at least one connecting pad, and the at least one connecting pad is only disposed in the at least one connection area.

3. The 3D chip package structure according to claim 2 further comprising at least one conductive pillar connected to the at least one connecting pad, wherein the at least one conductive pillar is disposed corresponding to the at least one connection area.

4. The 3D chip package structure according to claim 1, wherein the at least one connecting area is adjacent to an edge of the at least one memory partition.

5. The 3D chip package structure according to claim 1, wherein the at least one connecting area is more than two connecting areas, and the at least one connecting quiet zone is one connecting quiet zone disposed between the any two of connecting areas.

6. The 3D chip package structure according to claim 1, wherein the at least one connecting quiet zone is more than two connecting quiet zones, and each area of the connecting quiet zones are same or different.

7. The 3D chip package structure according to claim 5, wherein each area of the connecting areas are same or different.

8. The 3D chip package structure according to claim 3 further comprising:
a logic circuit device connected to the memory device through the at least one conductive pillar and comprising:
at least one circuit component, wherein a vertical projection of the at least one circuit component overlaps with a vertical projection of the at least one connecting quiet zone.

9. The 3D chip package structure according to claim 8, wherein the logic circuit device comprises at least one memory controller, and the at least one memory controller is electrically connected to the at least one conductive pillar.

10. The 3D chip package structure according to claim 1, wherein the memory device comprises at least one redistribution layer, and the redistribution layer is disposed between the memory wafer layer and the connecting layer.

11. The 3D chip package structure according to claim 10, wherein a thickness of the at least one redistribution layer is between 0.7 μm to 0.9 μm.

12. The 3D chip package structure according to claim 1, wherein the memory wafer layer comprises:
circuit components connected in parallel to each other and electrically connected to a power terminal for receiving a source voltage; and
a compensation circuit electrically connected to the circuit components for outputting a compensation voltage to the circuit components;
wherein at least one of the circuit components is away from the power terminal.

13. The 3D chip package structure according to claim 12, wherein the compensation circuit is electrically connected to one connecting pad for receiving a compensation source voltage.

14. The 3D chip package structure according to claim 12, wherein the compensation circuit is a low-dropout regulator.

15. The 3D chip package structure according to claim 12, wherein the compensation voltage is equal to the source voltage.

16. The 3D chip package structure according to claim 12, wherein the power terminal is electrically connected to one connecting pad.

17. The 3D chip package structure according to claim 1, further comprising:
a logic circuit device connected to the memory device and comprising:
circuit components connected in parallel to each other and electrically connected to a power terminal for receiving a source voltage; and
a compensation circuit electrically connected to the circuit components for outputting a compensation voltage to the circuit components;
wherein at least one of the circuit components is away from the power terminal.

18. The 3D chip package structure according to claim 17, wherein the compensation circuit is electrically connected to a connecting pad for receiving a compensation source voltage.

19. The 3D chip package structure according to claim 17, wherein the logic circuit device is packaged by a wire bonding process.

20. The 3D chip package structure according to claim 17, wherein the compensation voltage is equal to the source voltage.
